(19) United States
(12) Patent Application Publication
(10) Pub. No.: US 2026/0037042 A1
(43) Pub. Date: Feb. 5, 2026

(54) DATA TRANSMISSION BOX

(71) Applicant: TILTA INC., Burbank, CA (US)

(72) Inventors: Zhichao FENG, Shenzhen (CN); Wenping ZENG, Shenzhen (CN); Kefeng ZHOU, Shenzhen (CN)

(21) Appl. No.: 19/285,752

(22) Filed: Jul. 30, 2025

(30) Foreign Application Priority Data
Aug. 1, 2024 (CN) 202421858430.2

(51) Int. Cl. G06F 1/18; G06F 1/20; H05K 7/20

(52) U.S. Cl. CPC G06F 1/187; G06F 1/20; H05K 7/20136

(57) ABSTRACT

The present disclosure provides a data transmission box, including a housing, a read-write assembly, and a magnetic attachment assembly. The housing forms an installation cavity and features a card insertion port and a first opening. The read-write assembly includes a circuit board, a connector, and a data transmission interface. The circuit board is positioned within the installation cavity. The connector is attached to the circuit board and includes a card slot aligned with the card insertion port. The data transmission interface is connected to the circuit board, with one end exposed on the first opening. The magnetic attachment assembly is mounted on the housing. In operation, a memory card is inserted into the card slot through the card insertion port, and the data transmission interface is electrically connected to an electronic device to enable data transfer. The integrated magnetic attachment capability of the data transmission box introduced herein enhances multifunctionality.

### CROSS-REFERENCE TO RELATED APPLICATIONS

The present application for patent claims priority to and the benefit of pending Chinese Application No. 2024218584302, filed on Aug. 1, 2024, and hereby expressly incorporated by reference herein as if fully set forth below in its entirety and for all applicable purposes.

### TECHNICAL FIELD

The present disclosure pertains to the field of electronic device accessories, more particularly to a data transmission box.

### INTRODUCTION

Electronic devices such as smartphones, computers, and cameras are widely used in daily activities, including work, study, and photography, for processing documents, videos, photographs, and other data. The growing volume of generated data necessitates storage solutions such as solid-state drives, SD cards, and TF cards. Traditional data transmission boxes containing these storage modules typically connect to electronic devices via cables for data transfer. However, existing designs primarily focus on data transmission, lacking versatility to enhance practical usability in daily scenarios.

### BRIEF SUMMARY

Aspects of the present disclosure provide a data transmission box that overcomes the technical limitations of conventional single-function designs of data transmission boxes, thereby enhancing user convenience in daily scenarios.

Some aspects of the present disclosure provide:

A data transmission box including:
a housing having an installation cavity, with a card insertion port and a first opening;
a read-write assembly, including a circuit board positioned within the installation cavity; a connector attached to the circuit board, featuring a card slot aligned with the card insertion port; a data transmission interface connected to the circuit board, with one end exposed through the first opening; and
a magnetic attachment assembly mounted on the housing to enable magnetic attachment to a magnetically attractable object.

The disclosed data transmission box allows users to insert a memory card into the card slot through the card insertion port and connect the data transmission interface to an electronic device for data transfer. During data transmission, the integrated magnetic attachment capability of the data transmission box introduced herein enhances multifunctionality, significantly improving user convenience.

### BRIEF DESCRIPTION OF THE DRAWINGS

The following provides a brief description of the accompanying drawings for the implementation of exemplary embodiments of the present disclosure. Notably, the drawings represent only exemplary embodiments, and other derived configurations may be obtained by those skilled in the art without creative effort.

FIG. 1 is a diagram illustrating a data transmission box according to some aspects of the present disclosure.

FIG. 2 is a diagram illustrating the data transmission box according to some aspects of the present disclosure.

FIG. 3 is an exploded view of the data transmission box according to some aspects of the present disclosure.

FIG. 4 is a diagram illustrating the data transmission box according to some aspects of the present disclosure.

FIG. 5 is a diagram illustrating a second housing according to some aspects of the present disclosure.

FIG. 6 is a diagram illustrating a first housing according to some aspects of the present disclosure.

FIG. 7 is a diagram illustrating the data transmission box with an inserted memory card according to some aspects of the present disclosure.

### REFERENCE NUMERALS

10. data transmission box; 20. memory card;

1. housing; 10. data transmission box; 11. installation cavity; 111. first chamber; 112. second chamber; 12. card insertion port; 121. first card insertion port; 122. second card insertion port; 13. first opening; 14. second opening; 15. fixing pillar; 16. first housing; 161. first side surface; 162. air intake vent; 163. latch; 17. second housing; 171. second side surface; 172. guide vane; 1721. mounting groove; 1722. air guide channel; 1723. air passage; 173. latching groove; 174. accommodation groove; 18. peripheral surface; 181. air outlet vent;
2. read-write assembly; 21. circuit board; 211. first mounting side; 212. second mounting side; 213. through hole; 22. connector; 221. first connector; 222. second connector; 223. card slot; 23. data transmission interface; 24. data storage mounting base; 241. data storage mounting groove;
3. magnetic attachment assembly; 31. magnet; 32. cover;
4. cooling fan;
5. power supply interface;
6. indicator light.

The objectives, functional features, and advantages of this application will be further explained with reference to the embodiments and accompanying drawings.

### DETAILED DESCRIPTION

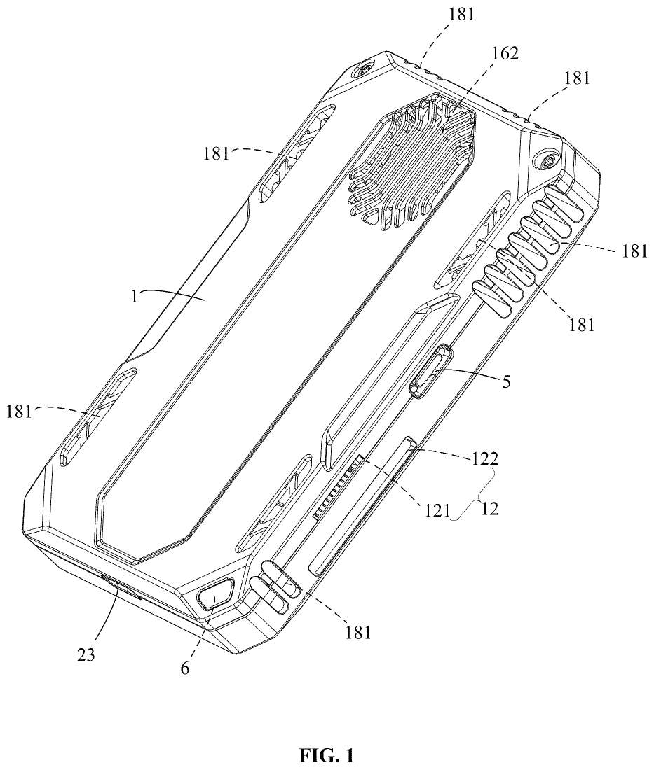

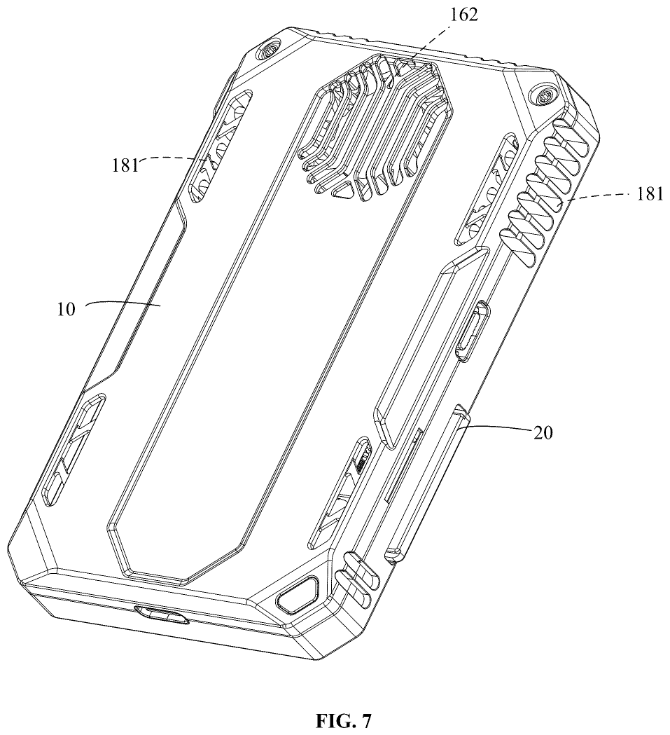

Referring to FIGS. 1-7, a data transmission box 10 can function as a read-write device that can receive (read) data from another device and send (write) data to a target device (e.g., memory, network). The data transmission box 10 includes a housing 1 with an installation cavity 11, a card insertion port 12, and a first opening 13. The data transmission box 10 can further include a read-write assembly 2, including a circuit board 21 positioned within the installation cavity 11, a connector 22 attached to the circuit board 21, featuring a card slot 223 aligned with the card insertion port 12, and a data transmission interface 23 provided on the circuit board 21, with one end exposed through the first opening 13; and a magnetic attachment assembly 3 mounted on the housing 1 to enable magnetic attachment to a magnetically attractable object.

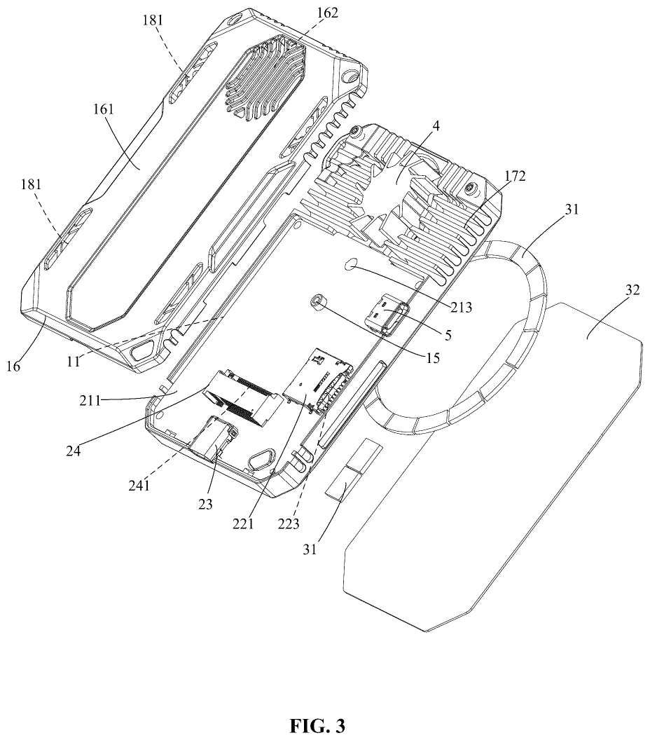

Referring to FIGS. 1-2 and 7, the present disclosure discloses a data transmission box 10. A user can insert a memory card 20 into the card slot 223 through the card insertion port 12, and the data transmission interface 23 can be electrically connected to an electronic device (e.g., via a cable) to initiate data transfer. The integrated magnetic attachment capability of the data transmission box 10 introduced herein enhances multifunctionality, significantly improving user convenience. For example, the magnetic attachment assembly 3 allows the data transmission box 10 to be magnetically attached to surfaces such as smartphones or heat sinks. In some aspects, the data transmission interface 23 is electrically connected to the circuit board 21, and so is the connector 22. The data transmission interface 23 can establish an electrical connection with an electronic device through a data cable (e.g., Universal Serial Bus (USB) cable) and is capable of supplying power to the data transmission box. When the data transmission interface is electrically connected to the electronic device, the latter can provide power to the various electronic components within the data transmission box. The memory card 20 can include, but is not limited to, a TransFlash (TF) card, a Secure Digital (SD) card, and so on. When the memory card 20 is inserted into the card slot 223, its controller can communicate with the circuit board 21 of the data transmission box 10 to perform data read/write operations. In some examples, the data transmission interface 23 can be a USB Type-C interface. On the other hand, referring to FIG. 3, the read-write assembly 2 of this disclosure can include a data storage mounting base 24 for installing a data storage device (e.g., hard disk, SSD). The data storage mounting base 24 is electrically connected to the circuit board 21 and includes a data storage mounting groove 241 for inserting the data storage device. Users can also choose to insert the hard disk into the data storage mounting groove 241 and electrically connect the data transmission interface 23 of the data transmission box 10 to an electronic device through a data cable, thereby enabling data transfer between the electronic device and the hard disk. With this configuration, the data transmission box 10 of this disclosure can perform read and write operations on multiple storage devices, including hard disks, TF cards, and SD cards, thus meeting various functional requirements of users. Additionally, the housing 1 of the data transmission box 10 can be equipped with a magnetic attachment assembly 3, which enables the housing 1 to be magnetically attached to another device (e.g., a mobile phone). As a result, users can conveniently operate the mobile phone while transferring data via the hard disk, such as engaging in handheld shooting or simultaneous recording and storage. It should be noted that although a mobile phone is used as an example here, the electronic device can also include a notebook computer, tablet, gaming console, and so on. In some aspects, a solid-state drive (SSD) can be used instead of the hard disk.

In some aspects, for the read-write operations of a memory card (e.g., TF cards and SD cards), the connectors 22 and card insertion ports 12 each include multiple units. Each connector 22 includes at least one card slot 223. The multiple connectors 22 include a first connector 221 and a second connector 222. The first connector 221 is configured for inserting a TF card, while the second connector 222 is configured for inserting an SD card. The multiple card insertion ports 12 include a first card insertion port 121 and a second card insertion port 122. Both the first connector 221 and the second connector 222 are connected to the circuit board 21. The first card insertion port 121 and the second card insertion port 122 are positioned on the housing 1 to align with the card slot 223 of the first connector 221 and the card slot 223 of the second connector 222, respectively. This allows the TF card to be inserted into the card slot 223 of the first connector 221 through the first card insertion port 121, and the SD card to be inserted into the card slot 223 of the second connector 222 through the second card insertion port 122. In other words, the first connector 221 serves as a TF connector 22, and the second connector 222 serves as an SD connector 22. In some aspects, the circuit board 21 includes opposing first mounting side 211 and second mounting side 212. The first connector 221 and the data transmission interface 23 are connected to the first mounting side 211, while the second connector 222 is connected to the second mounting side 212. This arrangement optimizes the use of space within the installation cavity 11 of the data transmission box 10. It is understandable that in some alternative implementations, a third connector can also be included, which likewise features a card slot. The housing 1 can further include a third card insertion slot to accommodate other memory cards, such as CF cards.

For the installation of a hard disk, please refer to FIG. 3. In some aspects, the housing 1 includes one or more fixing pillars 15 (one pillar 15 shown in FIG. 3). The end of the circuit board 21 distal to the data storage mounting base 24 is provided with through one or more holes 213. The fixing pillars 15 extend from the second mounting side 212 of the circuit board 21 toward the first mounting side 211 and pass through the through holes 213, serving to limit the position of the hard disk when it is inserted into the data storage mounting groove 241. In some aspects, a hard disk features positioning holes at one end. During installation, the user can insert one end of the hard disk into the data storage mounting groove 241, while the positioning holes at the other end engage with the fixing pillars 15, and then secured by fastening screws to the fixing pillars 15, thereby locking the hard disk in place. For removal, the screws can be loosened to release the hard disk, allowing it to be extracted from the data storage mounting groove 241.

Multiple fixing pillars 15 can be provided. This example describes two fixing pillars 15 positioned at varying distances from the data storage mounting base 24 to accommodate hard disks of different models and sizes, thereby enhancing the versatility of the data transmission box 10.

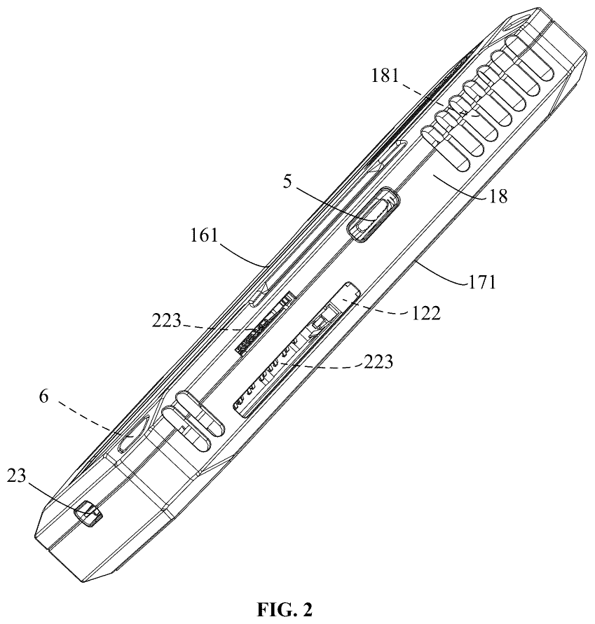

Referring to FIGS. 2-4, in some aspects, the data transmission box 10 further includes a cooling fan 4. The housing 1 includes a first side surface 161, a second side surface 171, and a peripheral surface 18, with the peripheral surface 18 located between the first side surface 161 and the second side surface 171. The cooling fan 4 is positioned within the installation cavity 11. The first side surface 161 is provided with at least one air intake vent 162, while the first side surface 161 and/or the peripheral surface 18 is provided with at least one air outlet vent 181. Both the air intake vent 162 and the air outlet vent 181 are in fluid (air) communication with the installation cavity 11. In some aspects, the configured cooling fan 4, air intake vent 162, and air outlet vent 181 facilitate air circulation between the interior and exterior of the housing 1, generating airflow to dissipate heat produced during the operation of the hard disk, TF card, SD card, or other electronic components, thereby preventing damage caused by excessive internal temperatures.

In some aspects, when the user establishes an electrical connection between the data transmission interface 23 and an electronic device, the electronic device can provide power to the data transmission box 10, thereby energizing components such as the circuit board 21, cooling fan 4, data storage mounting base 24, and connectors 22. This, in turn, enables the reading and/or writing of data from/to the hard disk or memory card 20.

Referring to FIG. 3, in some examples, the circuit board 21 can be electrically connected to a power supply interface 5. The housing 1 can be equipped with a second opening 14. One end of the power supply interface 5 is electrically connected to the circuit board 21, while the other end extends through the second opening 14. This setup allows the user to connect an external power source through the power supply interface 5. The external power source can supply power to the electronic components within the data transmission box 10, and the data transmission box 10 can further supply power to the electronic device through the data transmission interface 23. In one example, the power supply interface 5 can be a USB Type-C interface.

In some aspects, referring to FIGS. 3-6, the housing 1 includes multiple guide vanes 172. The installation cavity 11 includes a first chamber 111 and a second chamber 112. The circuit board 21 is installed in the first chamber 111, while the guide vanes 172 are attached to the walls of the second chamber 112, dividing the air outlet vent 181 that communicates with the second chamber 112 into multiple air outlet vents 181. This enhances the uniformity of airflow. In some aspects, the walls of the second chamber 112 near the air intake vent 162 and those far from the air intake vent 162 can both be equipped with guide vanes 172 to form multiple air guide channels 1722.

The ends of the multiple guide vanes 172 that are far from the air outlet vent 181 are arranged around the cooling fan 4 to form a mounting groove 1721 for accommodating the cooling fan 4. Two adjacent guide vanes 172 create an air guide channel 1722 to direct the airflow from the fan. This configuration allows the fan to directly channel air from the housing 1 into multiple air guide channels 1722, which is then expelled through the air outlet vent 181, thereby effectively dissipating heat from the electronic components inside the housing 1. In some aspects, some of the guide vanes 172 near the first chamber 111 are positioned on opposite sides of the fan, with their ends distal to the air outlet vent 181 arranged opposite each other to form an air passage 1723. The air passage 1723 facilitates air circulation between the first chamber 111 and the second chamber 112, allowing heat from the second chamber 112 to be expelled outside the housing 1.

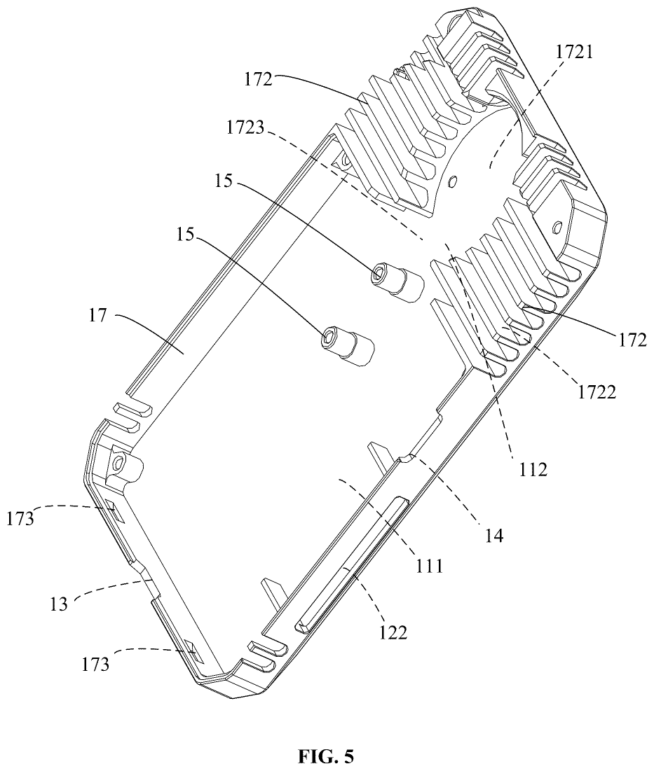

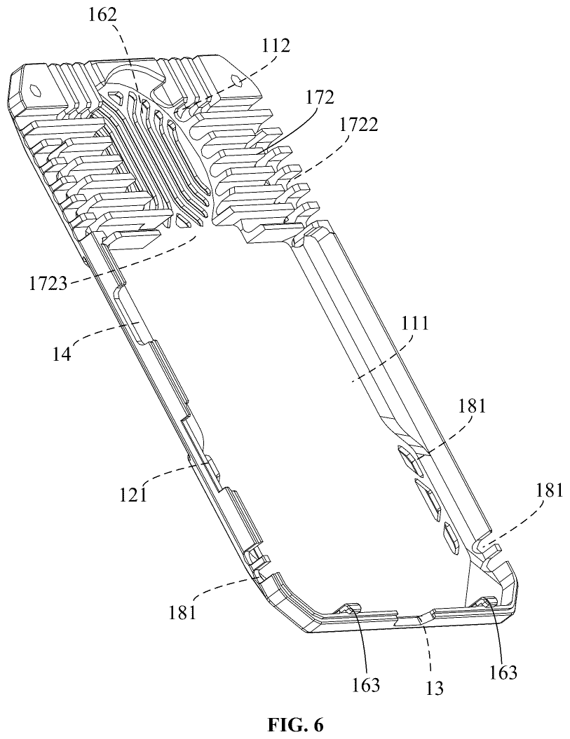

In some aspects, referring to FIGS. 5-6, the housing 1 includes a first housing 16 and a second housing 17. The first side surface 161 is located on the first housing 16, while the second side surface 171 is located on the second housing 17. The circumferential side surfaces of both the first housing 16 and the second housing 17 form the peripheral surface 18 of the housing 1. The air intake vent 162 and some of the air outlet vents 181 are provided on the first housing 16, while the second card insertion port 122 is provided on the second housing 17. The first housing 16 and the second housing 17 collectively form the first opening 13, the second opening 14, and the first card insertion port 121. The sides of the second housing 17 and the first housing 16 facing each other are both equipped with guide vanes 172. An installation cavity 11 is formed between the first housing 16 and the second housing 17. The magnetic attachment assembly 3 is connected to the side of the second housing 17 opposite the first housing 16. One end of the first housing 16 is provided with one or more latches 163, while the corresponding position on the second housing 17 is provided with one or more latching grooves 173. The other ends of the first housing 16 and the second housing 17 can be connected via screws or the like. During use, after the hard disk is installed, the latch 163 can be engaged with the latching groove 173, and the first housing 16 and the second housing 17 can be secured by tightening screws at the other ends. To remove the hard disk, the screws at one end of the first housing 16 and the second housing 17 can be loosened to separate the two housings.

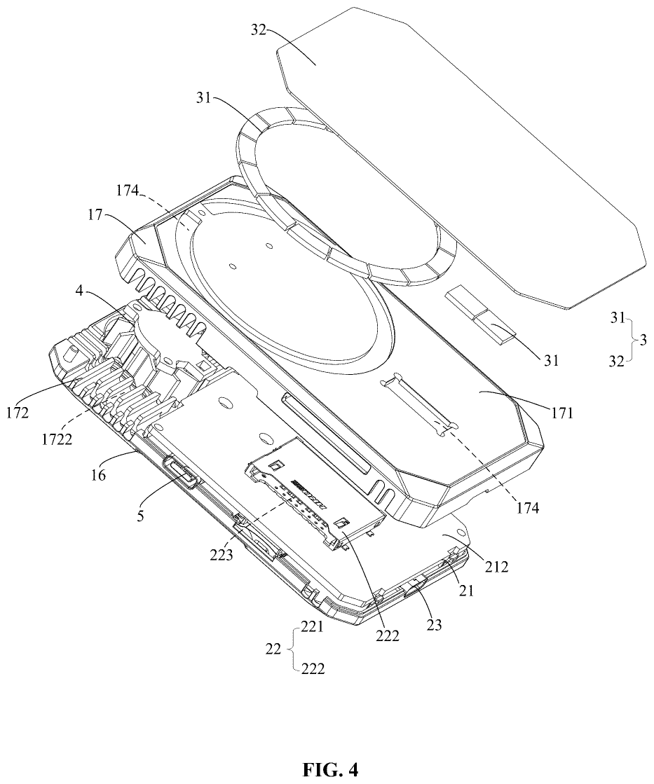

Referring to FIG. 4, in some aspects, the magnetic attachment assembly 3 includes a magnet 31 and a cover 32. The cover 32 is mounted on the side of the second housing 17 opposite the first housing 16, with the magnet 31 placed between the cover 32 and the second housing 17. In some aspects, the side of the second housing 17 opposite the first housing 16 is provided with an accommodation groove 174. Multiple magnets 31 are accommodated within the accommodation groove 174. In some aspects, the magnet 31 includes a ring-shaped magnet 31 and a magnet strip located below the ring-shaped magnet 31, suitable for magnetic attachment to electronic devices.

Referring to the drawings, in some aspects, the circuit board 21 can be equipped with an indicator light 6. The indicator light 6 is electrically connected to the circuit board 21 and is visible outside the housing 1, serving to indicate the power supply status.

As used in the claims, the indefinite articles “a” and “an” should be understood to mean “one or more” unless explicitly stated otherwise or unless the context clearly dictates a singular interpretation. The use of these articles does not limit the claimed invention to a single instance of the referenced element but rather encompasses multiple instances where applicable.

What is claimed is:

1. A data transmission box, comprising:
a housing configured to provide an installation cavity, a card insertion port, and a first opening;
a read-write assembly comprising a circuit board, a connector on the circuit board, and a data transmission interface on the circuit board, wherein the circuit board is disposed in the installation cavity;
wherein the connector includes a card slot, and the card slot communicates with the card insertion port;
wherein the data transmission interface comprises one end exposed through the first opening; and
a magnetic attachment assembly mounted on the housing, configured to enable the housing to be magnetically attached to a magnetically attractable object.

2. The data transmission box according to claim 1, wherein the card insertion port comprises a plurality of card insertion ports, and the connector comprises a plurality of connectors;
wherein each of the plurality of connectors is provided with at least one card slot;
wherein the plurality of connectors comprise a first connector and a second connector;
wherein the plurality of card insertion ports comprise a first card insertion port and a second card insertion port;
wherein the first connector and the second connector are respectively connected to the circuit board; and
wherein the first card insertion port and the second card insertion port are arranged on the housing, communicating with the card slot of the first connector and the card slot of the second connector, respectively.

3. The data transmission box according to claim 2, wherein the circuit board comprises oppositely provided first mounting side and second mounting side;
wherein the first connector and the data transmission interface are mounted on the first mounting side; and
wherein the second connector is mounted on the second mounting side.

4. The data transmission box according to claim 1, wherein the read-write assembly further comprises a data storage mounting base connected to the circuit board; and
wherein the data storage mounting base comprises a data storage mounting groove.

5. The data transmission box according to claim 4, wherein the housing comprises a fixing pillar;
wherein an end of circuit board away from data storage mounting base is provided with a through hole; and
wherein the fixing pillar protrudes toward the circuit board and penetrates the through hole, configured to limit movement of a data storage device in the data storage mounting groove.

6. The data transmission box according to claim 1, further comprising a cooling fan;
wherein the housing comprises a first side surface, a second side surface, and a peripheral surface, wherein the peripheral surface is located between the first side surface and the second side surface;
wherein the magnetic attachment assembly is mounted on the second side surface;
wherein the cooling fan is disposed in the installation cavity;
wherein the first side surface is provided with at least one air intake vent;
wherein the first side surface and the peripheral surface are each provided with at least one air outlet vent; and
wherein the air intake vent and the air outlet vent are in fluid communication with the installation cavity.

7. The data transmission box according to claim 1, further comprising a cooling fan;
wherein the housing comprises a first side surface, a second side surface, and a peripheral surface, wherein the peripheral surface is located between the first side surface and the second side surface;
wherein the magnetic attachment assembly is mounted on the second side surface;
wherein the cooling fan is disposed in the installation cavity;
wherein the first side surface is provided with at least one air intake vent;
wherein the first side surface is provided with at least one air outlet vent; and
wherein the air intake vent and the air outlet vent are in fluid communication with the installation cavity.

8. The data transmission box according to claim 6, wherein the housing comprises a plurality of guide vanes;
wherein the installation cavity comprises a first chamber and a second chamber;
wherein the circuit board is mounted in the first chamber; and
wherein the plurality of guide vanes are connected to an inner wall of the second chamber, forming a plurality of air guide channels in fluid communication with the air outlet vent.

9. The data transmission box according to claim 8, wherein ends of the plurality of guide vanes away from the air outlet vent are arranged around the cooling fan, forming a mounting groove for accommodating the cooling fan; and
wherein airflow from the cooling fan is directed along the air guide channels toward the air outlet vent.

10. The data transmission box according to claim 9, wherein one or more of the plurality of guide vanes proximal to the first chamber are oppositely provided on two sides of the cooling fan; and
wherein ends of the plurality of guide vanes distal to the air outlet vent are provided opposite each other, forming an air passage.

11. The data transmission box according to claim 6, wherein the magnetic attachment assembly comprises a magnet and a cover;
wherein the cover corresponds to the second side surface; and
wherein the magnet is provided between the cover and the second side surface.

12. The data transmission box according to claim 1, wherein the housing comprises a first housing and a second housing, wherein the first housing and the second housing are configured to form the installation cavity;
wherein a first end of the first housing or the second housing is provided with a latching groove, while a remaining one of the first housing and the second housing is provided with a latch engageable with the latching groove; and
wherein a second end of the first housing and the second housing is connected via screws.
